(19) United States
(12) Patent Application Publication
(10) Pub. No.: US 2021/0313984 A1
(43) Pub. Date: Oct. 7, 2021

(54) SEMICONDUCTOR DEVICE

(71) Applicant: RENESAS ELECTRONICS CORPORATION, Tokyo (JP)

(72) Inventor: Makoto HIGASHI, Tokyo (JP)

(21) Appl. No.: 17/182,085

(22) Filed: Feb. 22, 2021

(30) Foreign Application Priority Data
Apr. 2, 2020 (JP) 2020-066610

(51) Int. Cl. H03K 19/00; H03K 17/06; H03K 17/687

(52) U.S. Cl. CPC H03K 19/0013; H03K 17/6871; H03K 17/063

(57) ABSTRACT

A semiconductor device includes: a first wiring to which a power supply potential is supplied; a second wiring to which a ground potential is supplied; a logical circuit block including a power supply node, a ground node connected to the second wiring, and a plurality of logical circuits; and a switch circuit provided between the first wiring and the power supply node. The switch circuit includes a plurality of first P-channel type MOS transistors whose source-drain paths are connected between the first wiring and the power supply node. The plurality of first P-channel type MOS transistors are brought into an OFF state, a diode-connected state, or an ON state.

### CROSS-REFERENCE TO RELATED APPLICATIONS

The disclosure of Japanese Patent Application No. 2020-066610 filed on Apr. 2, 2020 including the specification, drawings and abstract is incorporated herein by reference in its entirety.

### BACKGROUND

This disclosure relates to a semiconductor device and is particularly applicable to a semiconductor device including a logic circuit unit.

A semiconductor device such as a microcontroller (hereinafter, referred to as MCU) is composed of a central processing unit (CPU), a memory device, a plurality of peripheral circuits constituting various peripheral functions, and others. The central processing unit can be regarded as a logic circuit unit composed of a plurality of logic circuits. Further, the plurality of peripheral circuits can also be regarded as a logic circuit unit composed of a plurality of logic circuits except an analog circuit.

### THERE ARE DISCLOSED TECHNIQUES LISTED BELOW

[Patent Document 1] Japanese Unexamined Patent Application Publication No. 2011-60401

[Patent Document 2] Japanese Unexamined Patent Application Publication No. 2014-99165

In order to reduce the current consumption during standby in a logic circuit unit of a semiconductor device, a power shutdown technique for shutting down the power supply of the logic circuit unit has been proposed (for example, Japanese Unexamined Patent Application Publication No. 2011-60401, Japanese Unexamined Patent Application Publication No. 2014-99165, etc.). Japanese Unexamined Patent Application Publication No. 2011-60401 also discloses a power control technique for an SRAM module.

### SUMMARY

The power shutdown technique is highly effective in reducing the current consumption of the logic circuit unit during standby. When a low current consumption MCU is used, it is the mainstream that the MCU is configured to execute an intermittent operation that repeats a normal operation state (RUN state) and a standby state (standby state). As to the recovery from the standby state to the normal operation state, a high-speed recovery is required. When the power shutdown is performed, the recovery time and current consumption may increase because a complicated start-up sequence is necessary. In addition, since the logic circuit unit whose power has been shut down is not supplied with power, it is impossible to retain information during standby.

On the other hand, with the miniaturization of the manufacturing process of the semiconductor device and the increase in the logic scale of logic circuits, the leakage current of the semiconductor device becomes apparent in a high temperature state.

An object of this disclosure is to provide a technique capable of reducing the current consumption of a logic circuit during standby and recovering from a standby state to a normal operation state in a short time even when the semiconductor device is in a high temperature state.

The other object and novel feature will become apparent from the description of this specification and attached drawings.

The summary of the typical embodiment in this disclosure will be simply described as follows.

A semiconductor device according to an embodiment includes: a first wiring to which a power supply potential is supplied; a second wiring to which a ground potential is supplied; a logical circuit block including a power supply node, a ground node connected to the second wiring, and a plurality of logical circuits; and a switch circuit provided between the first wiring and the power supply node. The switch circuit includes a plurality of first P-channel type MOS transistors whose source-drain paths are connected between the first wiring and the power supply node. The plurality of first P-channel type MOS transistors are brought into an OFF state, a diode-connected state, or an ON state.

With the semiconductor device according to the embodiment described above, it is possible to reduce the leakage current of the logic circuit even in a high temperature state.

### BRIEF DESCRIPTION OF THE DRAWINGS

FIG. 1 is a diagram showing a configuration example of a semiconductor device according to the first embodiment.

FIG. 2 is a diagram illustrating a configuration example of a logical circuit block, a switch circuit, and a holding circuit of FIG. 1.

FIG. 3 is a diagram showing a configuration example of a buffer circuit of FIG. 2.

FIG. 4 is a diagram illustrating the states of the switch circuit of FIG. 2.

FIG. 5 is a circuit diagram showing a switch circuit according to a comparative example.

FIG. 6 is a diagram showing a configuration example of a semiconductor device according to a modification.

FIG. 7 is a diagram showing a configuration example of a buffer circuit of FIG. 6.

FIG. 8 is a diagram illustrating a configuration example of a semiconductor device according to the second embodiment.

FIG. 9 is a diagram illustrating a supply path of a power supply potential of the semiconductor device of FIG. 8.

FIG. 10 is a diagram showing the operation modes of the semiconductor device and the state transition thereof.

FIG. 11 is a diagram illustrating the operation modes of FIG. 10 and the state of each functional block of FIG. 9.

FIG. 12 is a diagram showing an example of a setting state of a control register in a normal operation mode.

FIG. 13 is a diagram showing an example of the setting state of the control register in a first standby mode.

FIG. 14 is a diagram showing an example of the setting state of the control register in a second standby mode.

FIG. 15 is a diagram showing an example of the setting state of the control register in a shutdown mode.

FIG. 16 is a diagram showing an example of the setting state of the control register during the transition from the second standby mode to the normal operation state.

### DETAILED DESCRIPTION

Hereinafter, embodiments and examples of the present invention will be described with reference to the drawings. However, the same components are denoted by the same reference characters and the repetitive description thereof may be omitted in the following description. Note that the drawings may be represented schematically as compared to actual aspects in order to make the description clearer, but the drawings are mere examples and do not limit the interpretation of the present invention.

### First Embodiment

(Configuration Example of Semiconductor Device)

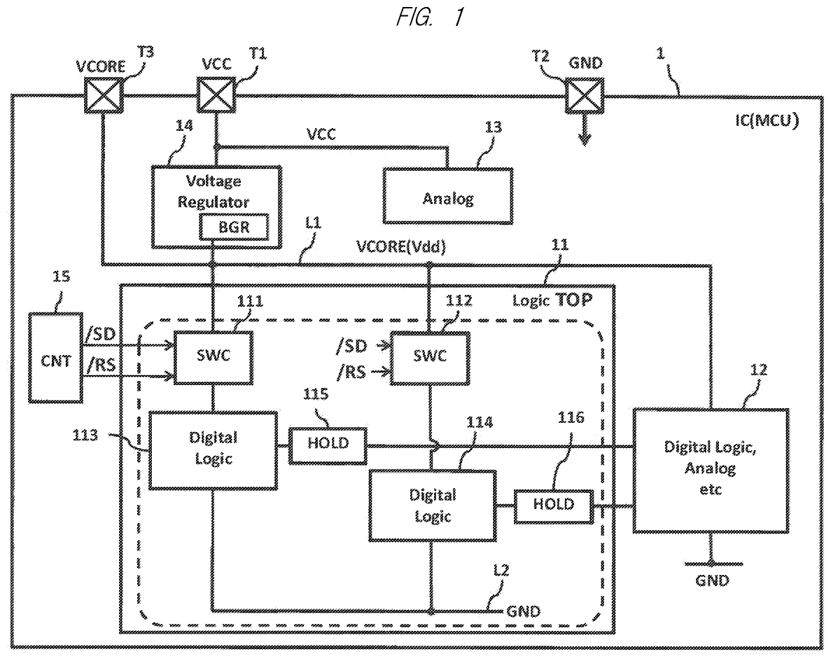

FIG. 1 is a diagram showing a configuration example of a semiconductor device according to the first embodiment.

A semiconductor device 1 is formed on one semiconductor chip such as single crystal silicon by using a known manufacturing method of a CMOS transistor. The semiconductor device 1 is, for example, a microcontroller (hereinafter, also referred to as MCU). The semiconductor device 1 includes an external terminal T1 to which a power supply potential VCC which is a first reference potential is supplied, an external terminal T2 to which a ground potential GND which is a second reference potential lower than the first reference potential is supplied, and an external terminal T3 to which a core voltage VCORE is supplied. The core voltage VCORE has, for example, a potential between the power supply potential VCC and the ground potential GND.

The semiconductor device 1 further includes a logic circuit unit 11, a circuit unit 12, an analog circuit 13, a power supply circuit 14, and a control circuit (CNT) 15. The logic circuit unit 11 can be regarded as a central processing unit (CPU) of the MCU in one example. The circuit unit 12 includes a digital logic circuit such as a timer circuit, an analog circuit such as a digital-to-analog conversion circuit, and the like, and is connected to the logic circuit unit 11 so as to receive an output from the logic circuit unit 11. The analog circuit 13 is configured to receive the power supply potential VCC supplied to the first external terminal T1, and can be, for example, an analog-to-digital conversion circuit (ADC). The circuit unit 12 and the analog circuit can be regarded as peripheral circuits constituting the peripheral functions of the MCU.

The power supply circuit 14 includes a regulator configured to generate the core voltage VCORE (Vdd) (hereinafter, core voltage VCORE (Vdd) is sometimes referred to as Vdd) by stepping down the power supply potential VCC supplied to the first external terminal T1 based on the reference potential generated by a bandgap reference circuit BGR. The core voltage VCORE (Vdd) generated by the power supply circuit 14 is supplied to the logic circuit unit 11 and the circuit unit 12. Note that it is also possible to use the core voltage VCORE supplied to the third external terminal T3 as the core voltage VCORE (Vdd).

The control circuit (CNT) 15 generates a shutdown signal/SD and a standby signal/RS, and controls the normal operation state, the standby state, and the shutdown state of the logic circuit unit 11. The shutdown signal/SD is set to the first state such as the high level in the normal operation state, and is set to the second state such as the low level in the shutdown state. The standby signal/RS is set to the first state such as the high level in the normal operation state, and is set to the second state such as the low level in the standby state. The shutdown signal/SD can be referred to also as an inverting shutdown signal, and the standby signal/RS can be referred to also as an inverting standby signal. The shutdown signal/SD can be referred to also as the first control signal, and the standby signal/RS can be referred to also as the second control signal. Further, the standby signal/RS can be rephrased as a resume standby signal, and the standby state can be rephrased as a resume standby state.

In this example, the logic circuit unit 11 includes two switch circuits (SWC) 111 and 112 provided on the side of the core voltage VCORE (Vdd), two logic circuit blocks (Digital Logic) 113 and 114, and two holding circuits (HOLD) 115 and 116. The logic circuit block 113 is connected via the switch circuit (first switch circuit) 111 to the power supply wiring (first wiring) L1 to which the core voltage VCORE (Vdd) is supplied, and is connected to the ground wiring (second wiring) L2 to which the ground potential GND is supplied. The output of the logic circuit block 113 is supplied to the circuit unit 12 via the holding circuit 115. The logic circuit block 114 is connected via the switch circuit (first switch circuit) 112 to the power supply wiring L1 to which the core voltage VCORE (Vdd) is supplied, and is connected to the ground wiring L2 to which the ground potential GND is supplied. The output of the logic circuit block 114 is supplied to the circuit unit 12 via the holding circuit 116.

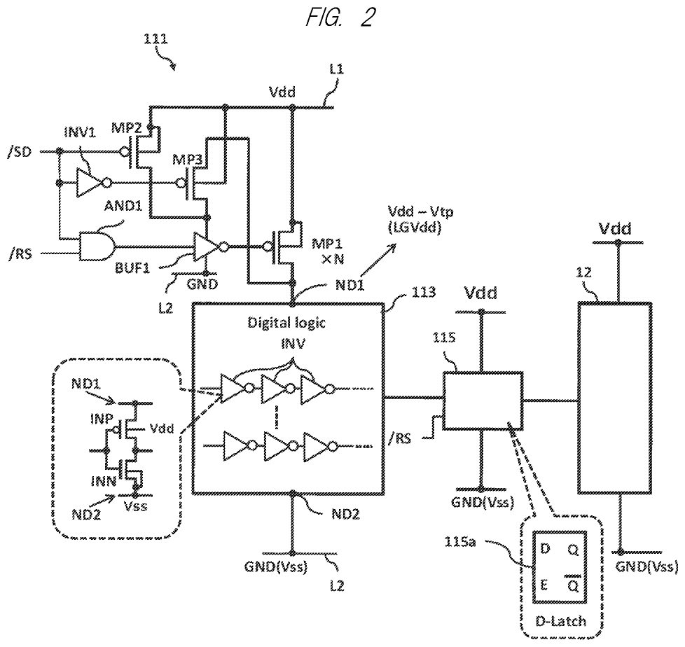

Each of the switch circuits 111 and 112 includes a plurality of P-channel type MOS transistors MP1 whose operation is controlled based on the shutdown signal/SD and the standby signal/RS as shown in FIG. 2 described later. The source-drain paths of the plurality of P-channel type MOS transistors are connected in parallel to each other.

(Specific Configuration Example)

Next, a specific configuration example will be described with the logic circuit block 113, the switch circuit 111, and the holding circuit 115 taken as typical examples. The configuration of the logic circuit block 114, the switch circuit 112, and the holding circuit 116 can be the same as the configuration of the logic circuit block 113, the switch circuit 111, and the holding circuit 115.

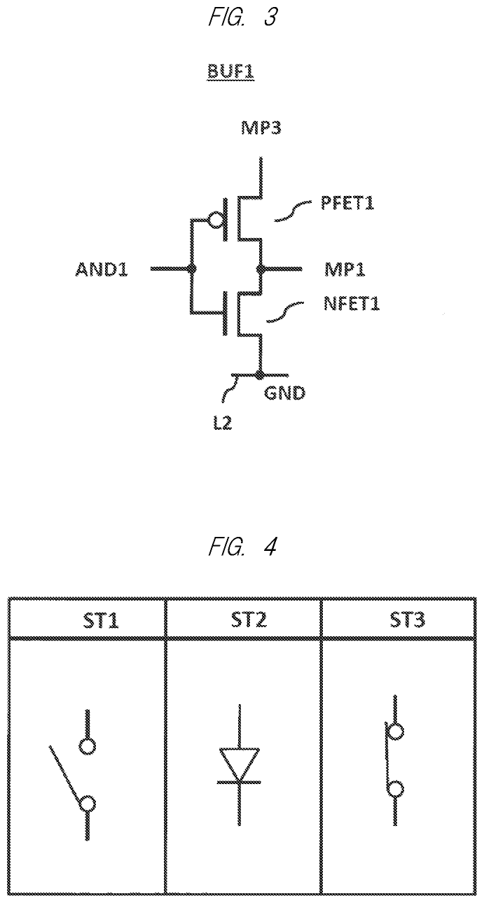

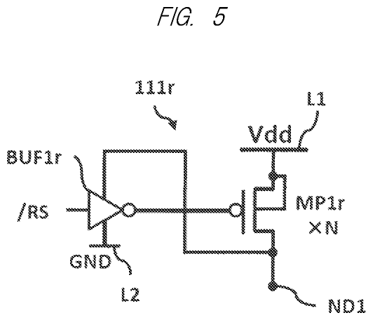

FIG. 2 is a diagram illustrating a configuration example of the logic circuit block 113, the switch circuit 111, and the holding circuit 115 of FIG. 1. FIG. 3 is a diagram showing a configuration example of a buffer circuit BUF1 of FIG. 2. FIG. 4 is a diagram illustrating a state of the switch circuit 111 of FIG. 2.

(Configuration Example of Switch Circuit)

The switch circuit 111 includes a plurality of P-channel type MOS transistors (first P-channel type MOS transistors) MP1, a P-channel type MOS transistor (second P-channel type MOS transistor) MP2, a P-channel type MOS transistor (third P-channel type MOS transistor) MP3, the buffer circuit BUF1, an inverter INV1, and an AND circuit AND1.

The plurality of P-channel type MOS transistors MP1 are, for example, N pieces of P-channel type MOS transistors MP1. Each of the gate electrodes of the plurality of P-channel type MOS transistors MP1 is connected to the output of the buffer circuit BUF1. Each of the source electrodes of the plurality of P-channel type MOS transistors MP1 is connected to the power supply wiring L1 to which the core voltage VCORE (Vdd) is supplied. Each of the drain electrodes of the plurality of P-channel type MOS transistors MP1 is connected to the power supply node ND1 of the logic circuit block 113. Namely, the source-drain paths of the plurality of P-channel type MOS transistors are connected in parallel to each other between the power supply wiring L1 and the power supply node ND1.

As shown in FIG. 3, the buffer circuit BUF1 includes a P-channel type MOS transistor (fourth P-channel type MOS transistor) PFET1 and an N-channel type MOS transistor (first N-channel type MOS transistor) NFET1.

The gate of the P-channel type MOS transistor PFET1 serves as the input of the buffer circuit BUF1 and is connected to the output of the AND circuit AND1. The source of the P-channel type MOS transistor PFET1 is connected to the drain of the P-channel type MOS transistor MP3. Namely, the source of the P-channel type MOS transistor PFET1 is connected to the power supply node ND1 of the logic circuit block 113, that is, the drain electrodes of the plurality of P-channel type MOS transistors MP1 via the source-drain path of the P-channel type MOS transistor MP3. The drain of the P-channel type MOS transistor PFET1 serves as the output of the buffer circuit BUF1 and is connected to the gate electrodes of the plurality of P-channel type MOS transistors MP1.

The gate of the N-channel type MOS transistor NFET1 serves as the input of the buffer circuit BUF1 and is connected to the output of the AND circuit AND1. The source of the N-channel type MOS transistor NFET1 is connected to the ground wiring L2 to which the ground potential GND is supplied. The drain of the N-channel type MOS transistor NFET1 serves as the output of the buffer circuit BUF1 and is connected to the gate electrodes of the plurality of P-channel type MOS transistors MP1.

The P-channel type MOS transistor MP2 has a gate connected so as to receive the shutdown signal/SD, a source connected to the power supply wiring L1 to which the core voltage VCORE (Vdd) is supplied, and a drain connected to the drain of the P-channel type MOS transistor MP3.

The inverter INV1 has an input connected so as to receive the shutdown signal/SD and an output connected to the gate of the P-channel type MOS transistor MP3.

The AND circuit AND1 has a first input connected so as to receive the shutdown signal/SD, a second input connected so as to receive the standby signal/RS, and an output connected to the input of the buffer circuit BUF1.

(Operation and State of Switch Circuit)

The switch circuit 111 can take three states while the power supply circuit 14 is generating the core voltage VCORE (Vdd). The three states include a shutdown state, a standby state, and a normal operation state.

In the shutdown state, the P-channel type MOS transistor MP1 is brought into the OFF state as shown in the first state ST1 of FIG. 4. Therefore, in the first state ST1, the power supply wiring L1 and the power supply node ND1 are not connected (non-conduction state).

In the standby state, the P-channel type MOS transistor MP1 is brought into the diode-connected state as shown in the second state ST2 of FIG. 4. Therefore, in the second state ST2, a diode is connected between the power supply wiring L1 and the power supply node ND1.

In the normal operation state, the P-channel type MOS transistor MP1 is brought into the ON state as shown in the third state ST3 of FIG. 4. Therefore, in the third state ST3, the power supply wiring L1 and the power supply node ND1 are connected (conduction state).

Therefore, the switch circuit 111 can be regarded as a voltage control circuit that controls the potential of the power supply node ND1 of the logic circuit block 113.

In this specification, the state in which the shutdown signal/SD is set to the low level is defined as the shutdown state. The state in which the shutdown signal/SD is set to the high level and the standby signal/RS is set to the low level is defined as the standby state. The state in which the shutdown signal/SD is set to the high level and the standby signal/RS is set to the high level is defined as the normal operation state.

The shutdown state, the standby state, and the normal operation state will be described below.

(Shutdown State)

When the shutdown signal/SD is set to the low level, the P-channel type MOS transistor MP2 is brought into the ON state and the P-channel type MOS transistor MP3 is brought into the OFF state. Since the output of the AND circuit AND1 becomes the low level, the output of the buffer circuit BUF1 becomes the high level. Consequently, as shown in FIG. 4, the plurality of P-channel type MOS transistors MP1 are brought into the OFF state, which corresponds to the first state ST1. Therefore, the switch circuit 111 does not supply the core voltage VCORE (Vdd) to the logic circuit block 113, and the logic circuit block 113 is brought into the power shutdown state.

Therefore, since the electrical connection between the power supply wiring L1 and the power supply node ND1 of the logic circuit block 113 is cut off, the leakage current of the plurality of transistors constituting the logic circuit block 113 can be cut off. As a result, the current consumption of the semiconductor device 1 can be reduced even when the semiconductor device 1 is in a high temperature state.

(Standby state)

When the shutdown signal/SD is set to the high level and the standby signal/RS is set to the low level, the P-channel type MOS transistor MP2 is brought into the OFF state and the P-channel type MOS transistor MP3 is brought into the ON state. Since the output of the AND circuit AND1 becomes the low level, the P-channel type MOS transistor PFET1 of the buffer circuit BUF1 is brought into the ON state. Consequently, since the gate electrode and the drain electrode of the P-channel type MOS transistor MP1 are connected via the source-drain path of the P-channel type MOS transistor PFET1 and the source-drain path of the P-channel type MOS transistor MP3, as shown in FIG. 4, the plurality of P-channel type MOS transistors MP1 are brought into the diode-connected state, which corresponds to the second state ST2. Therefore, the switch circuit 111 supplies the first potential LGVdd (LGVdd=Vdd−Vtp), which is lower than the core voltage VCORE (Vdd) by the threshold voltage (Vtp) of the diode, to the logic circuit block 113.

A potential difference between the first potential LGVdd and the ground potential Vss is supplied to the logic circuit block 113. Therefore, the internal logic circuit constituting the logic circuit block 113 can hold the signal state in the normal operation state. Further, since the potential difference between the first potential LGVdd and the ground potential Vss is smaller than the potential difference between the power supply potential Vdd and the ground potential Vss, it is possible to reduce the leakage current of the plurality of transistors constituting the logic circuit block 113. As a result, the current consumption of the logic circuit block 113 in the standby state can be reduced.

(Normal Operation State)

When the shutdown signal/SD is set to the high level and the standby signal/RS is set to the high level, the P-channel type MOS transistor MP2 is brought into the OFF state and the P-channel type MOS transistor MP3 is brought into the ON state. Since the output of the AND circuit AND1 becomes the high level, the output of the buffer circuit BUF1 becomes the low level. Consequently, as shown in FIG. 4, the plurality of P-channel type MOS transistors MP1 are brought into the ON state, which corresponds to the third state ST3. Therefore, the switch circuit 111 supplies the core voltage VCORE (Vdd) to the logic circuit block 113.

Since the logic circuit block 113 recovers from the standby state to the normal operation state while maintaining the signal state held in the standby state, it is possible to perform the signal processing in the normal operation from the held signal state. The recovery from the standby state to the normal operation state only requires the change of the signal level of the standby signal/RS, and does not require a complicated start-up sequence, so that the recovery time and current consumption are not increased.

(Configuration Example of Logic Circuit Block)

The logic circuit block 113 includes a plurality of logic circuits, and the power supply terminals and the ground terminals of the plurality of logic circuits are connected to the power supply node ND1 and the ground node ND2, respectively. In this example, the logic circuit block 113 is represented as including a plurality of inverters INV. As shown in the enlarged view, the inverter INV includes a P-channel type MOS transistor INP and an N-channel type MOS transistor INN, and a source-drain path of the P-channel type MOS transistor INP and a source-drain path of the N-channel type MOS transistor INN are connected in series between the power supply node ND1 and the ground node ND2. The gate electrode of the P-channel type MOS transistor INP and the gate electrode of the N-channel type MOS transistor INN are connected to each other and serve as an input terminal of the inverter INV. The common connection point between the source-drain path of the P-channel type MOS transistor INP and the source-drain path of the N-channel type MOS transistor INN serves as an output terminal of the inverter INV. The P-channel type MOS transistor INP is formed in an N-type well formed in a semiconductor chip. The substrate gate of the P-channel type MOS transistor INP is composed of the N-type well, and the N-type well is connected to the power supply potential Vdd. Also, the N-channel type MOS transistor INN is formed in a P-type well formed in a semiconductor chip. The substrate gate of the N-channel type MOS transistor INN is composed of the P-type well, and the P-type well is connected to the ground potential Vss. Note that the internal configuration of the logic circuit block 113 is not limited to a plurality of inverters INV. The logic circuit block 113 may include a plurality of AND circuits, a plurality of NAND circuits, a plurality of OR circuits, a plurality of NOR circuits, a plurality of flip-flop circuits, and the like in addition to the plurality of inverters INV.

(Configuration Example of Holding Circuit)

The holding circuit 115 holds the output of the logic circuit block 113. The holding circuit 115 can be configured by, for example, a D-latch circuit (D-Latch) 115a. In the D-latch circuit 115a, the standby signal/RS is input to an enable terminal E, the output of the logic circuit block 113 is connected to a data terminal D, and the input of the circuit unit 12 is connected to an output Q. In this example, one holding circuit 115 is depicted as a representative, but the holding circuit is not limited to this. When the logic circuit block 113 has a plurality of outputs and the circuit unit 12 has a plurality of inputs, a plurality of holding circuits 115 are provided in such a manner that one holding circuit 115 is provided each between the plurality of outputs of the logic circuit block 113 and the plurality of inputs of the circuit unit 12.

In the case of the standby state, the high level of the signal output from the logic circuit block 113 is the potential corresponding to the first potential LGVdd (LGVdd=Vdd−Vtp), and the low level of the signal output from the logic circuit block 113 is the potential corresponding to the ground potential Vss. On the other hand, since the power supply potential Vdd and the ground potential Vss are supplied to the circuit unit 12 provided on the subsequent stage of the logic circuit block 113, if the high level of the signal output from the logic circuit block 113 is input to the circuit unit 12, it may cause the propagation of an indefinite signal in the circuit unit 12 or the occurrence of a through current in the circuit unit 12. In order to prevent this, the holding circuit 115 for holding the output signal of the logic circuit block 113 is provided between the logic circuit block 113 and the circuit unit 12. Since the power supply potential Vdd and the ground potential Vss are supplied to the holding circuit 115, the high level of the output of the holding circuit 115 is the power supply potential Vdd, and the low level of the output of the holding circuit 115 is the ground potential Vss. Accordingly, it is possible to suppress the propagation of an indefinite signal and the occurrence of a through current in the circuit unit 12.

(Comparative Example)

FIG. 5 is a circuit diagram showing a switch circuit according to a comparative example.

A switch circuit 111r includes a buffer circuit BUF1r and a plurality of P-channel type MOS transistors MP1r. The buffer circuit BUF1r includes an input and an output that receive the standby signal/RS. The plurality of P-channel type MOS transistors MP1r are N pieces of P-channel type MOS transistors MP1. Each of the gate electrodes of the plurality of P-channel type MOS transistors MP1r is connected to the output of the buffer circuit BUF1r. Each of the source electrodes of the plurality of P-channel type MOS transistors MP1r is connected to the power supply wiring L1 to which the core voltage VCORE (Vdd) is supplied. Each of the drain electrodes of the plurality of P-channel type MOS transistors MP1r is connected to the power supply node ND1 of the logic circuit block 113. Namely, the source-drain paths of the plurality of P-channel type MOS transistors are connected in parallel to each other between the power supply wiring L1 and the power supply node ND1. The buffer circuit BUF1r has the same configuration as the buffer circuit BUF1 shown in FIG. 3.

The switch circuit 111r has a normal operation state and a standby state. The high level of the standby signal/RS is the normal operation state, and the low level of the standby signal/RS is the standby state.

In the case of the standby state, the P-channel type MOS transistor PFET1 in the buffer circuit BUF1r is brought into the ON state based on the low level of the standby signal/RS. Also, the N-channel type MOS transistor NFET1 in the buffer circuit BUF1r is brought into the OFF state based on the low level of the standby signal/RS. When the P-channel type MOS transistor PFET1 is brought into the ON state, the drains and the gates of the plurality of P-channel type MOS transistors MP1r have the same voltage. Therefore, the plurality of P-channel type MOS transistors MP1 are brought into the diode-connected state as shown in the second state ST2 of FIG. 4. Accordingly, the drain voltage of the plurality of P-channel type MOS transistors MP1r, that is, the voltage of the power supply node ND1 of the logic circuit block 113 becomes the first potential LGVdd (LGVdd=Vdd−Vtp) which is lower than the core voltage VCORE (Vdd) by the threshold voltage (Vtp) of the plurality of P-channel type MOS transistors MP1r.

In the case of the normal operation state, the P-channel type MOS transistor PFET1 in the buffer circuit BUF1r is brought into the OFF state based on the high level of the standby signal/RS. Also, the N-channel type MOS transistor NFET1 in the buffer circuit BUF1r is brought into the ON state based on the high level of the standby signal/RS. Therefore, the plurality of P-channel type MOS transistors MP1 are brought into the ON state as shown in the third state ST3 of FIG. 4. Since the plurality of P-channel type MOS transistors MP1 are brought into the ON state, the voltage of the power supply node ND1 of the logic circuit block 113 becomes the power supply potential Vdd.

The difference between the switch circuit 111 of FIG. 3 and the switch circuit 111r of FIG. 5 is that the switch circuit 111 has the shutdown state. By providing the shutdown state, the number of circuit elements constituting the switch circuit 111 increases as compared with that of the switch circuit 111r. However, since the increased circuit elements (MP2, MP3, INV1, AND1) are extremely small in size as compared to the overall size of the plurality of P-channel type MOS transistors MP1, the increase in the area of the switch circuit 111 does not cause any particular problem. According to the first embodiment, the following effects can be obtained.

1) Although the leakage current of a semiconductor device becomes apparent in a high temperature state along with the miniaturization of the manufacturing process of the semiconductor device and the increase in the logic scale of logic circuits, since the switch circuit 111 is provided with the shutdown state, the current consumption of the semiconductor device 1 can be reduced even when the semiconductor device 1 is in a high temperature state such as 85° C. 2) When the switch circuit 111 is in the standby state, the potential difference between the first potential LGVdd (LGVdd=Vdd−Vtp) and the ground potential Vss is supplied to the logic circuit block 113. Therefore, the internal logic circuit constituting the logic circuit block 113 can hold the signal state in the normal operation state.

3) Since the potential difference between the first potential LGVdd and the ground potential Vss is smaller than the potential difference between the power supply potential Vdd and the ground potential Vss, it is possible to reduce the leakage current of a plurality of transistors constituting the logic circuit block 113. As a result, the current consumption of the logic circuit block 113 in the standby state can be reduced.

4) The recovery from the standby state to the normal operation state can be made in a short time. The recovery from the standby state to the normal operation state only requires the change of the signal level of the standby signal/RS, and does not require a complicated start-up sequence, so that the recovery time and current consumption are not increased.

(Modification)

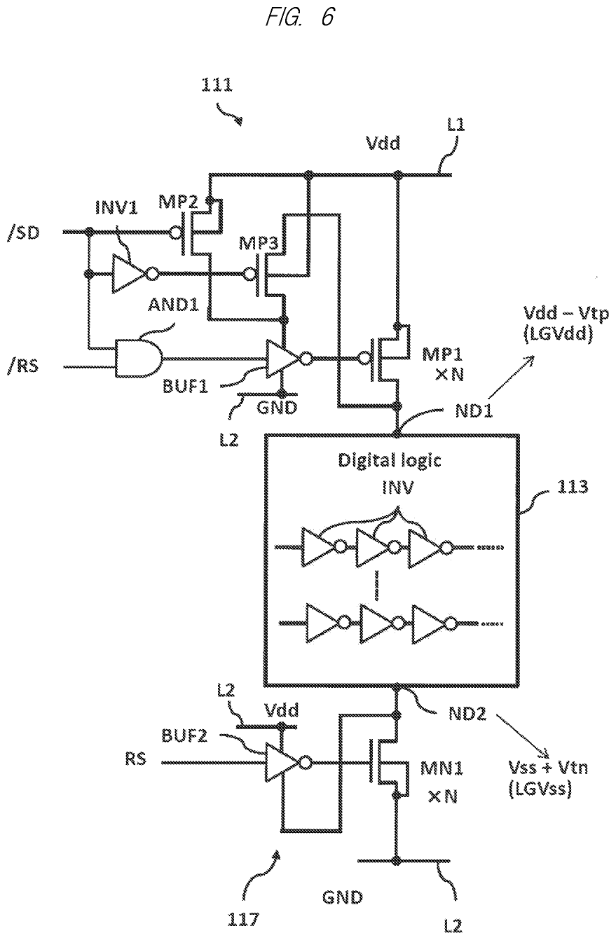

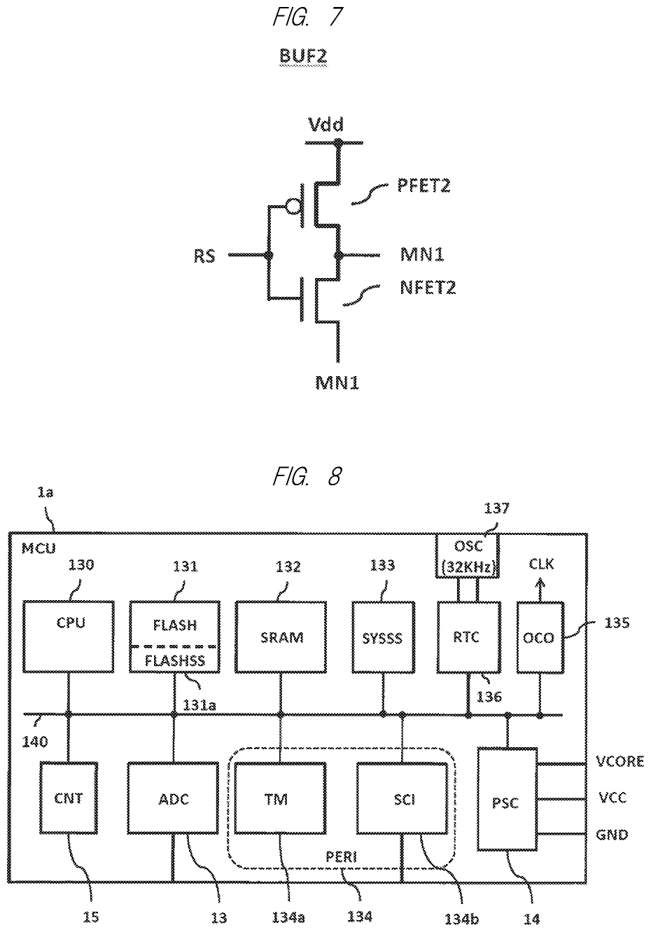

FIG. 6 is a diagram showing a configuration example of a semiconductor device according to a modification. FIG. 7 is a diagram showing a configuration example of a buffer circuit BUF2 of FIG. 6.

The difference between FIG. 6 and FIG. 2 is that a switch circuit 117 is provided between the ground node ND2 of the logic circuit block 113 and the ground wiring L2 in FIG. 6. Since the other configuration of FIG. 6 is the same as the configuration of FIG. 2, the repetitive description will be omitted. Hereinafter, the differences from FIG. 2 will be mainly described.

The switch circuit 117 includes the buffer circuit BUF2 and a plurality of N-channel type MOS transistors MN1. The buffer circuit BUF2 includes an input that receives the standby signal RS and an output. The plurality of N-channel type MOS transistors MN1 are, for example, N pieces of N-channel type MOS transistors MN1. Each of the gate electrodes of the plurality of N-channel type MOS transistors MN1 is connected to the output of the buffer circuit BUF2. Each of the source electrodes of the plurality of N-channel type MOS transistors MN1 is connected to the ground wiring L2 to which the ground potential GND is supplied. Each of the drain electrodes of the plurality of N-channel type MOS transistors MN1 is connected to the ground node ND2 of the logic circuit block 113. Namely, the source-drain paths of the plurality of N-channel type MOS transistors are connected in parallel to each other between the ground wiring L2 and the ground node ND2.

As shown in FIG. 7, the buffer circuit BUF2 includes a P-channel type MOS transistor (second P-channel type MOS transistor) PFET2 and an N-channel type MOS transistor (second N-channel type MOS transistor) NFET2. The gate of the P-channel type MOS transistor PFET2 is connected to the input of the buffer circuit BUF2. The source of the P-channel type MOS transistor PFET2 is connected to the power supply wiring L1 to which the power supply potential Vdd is supplied. The drain of the P-channel type MOS transistor PFET2 is connected to the output of the buffer circuit BUF2. The gate of the N-channel type MOS transistor NFET2 is connected to the input of the buffer circuit BUF2. The source of the N-channel type MOS transistor NFET2 is connected to the ground node ND2 of the logic circuit block 113, that is, the drain electrodes of the plurality of N-channel type MOS transistors MN1. The drain of the N-channel type MOS transistor NFET2 is connected to the output of the buffer circuit BUF2. Namely, the source-drain path of the P-channel type MOS transistor PFET2 and the source-drain path of the N-channel type MOS transistor NFET2 are connected in series between the power supply wiring L1 and the ground node ND2.

Note that the switch circuit 117 and the buffer circuit BUF2 can be regarded as a voltage control circuit that controls the potential of the ground node ND2 of the logic circuit block 113.

The P-channel type MOS transistor PFET2 in the buffer circuit BUF2 is brought into the OFF state based on the high level of the standby signal RS. Also, the N-channel type MOS transistor NFET2 in the buffer circuit BUF2 is brought into the ON state based on the high level of the standby signal RS. When the N-channel type MOS transistor NFET2 is brought into the ON state, the drains and the gates of the plurality of N-channel type MOS transistors MN1 have the same voltage. Therefore, the plurality of N-channel type MOS transistors MN1 are brought into the diode-connected state. Accordingly, the drain voltage of the plurality of P-channel type MOS transistors MP1, that is, the voltage of the ground node ND2 of the logic circuit block 113 becomes a second potential LGVss (LGVss=Vss+Vtn) which is higher than the ground potential Vss by the threshold voltage (Vtn) of the diode.

On the other hand, the P-channel type MOS transistor PFET2 in the buffer circuit BUF2 is brought into the ON state based on the low level of the standby signal RS. The N-channel type MOS transistor NFET2 in the buffer circuit BUF2 is brought into the OFF state based on the low level of the standby signal RS. When the P-channel type MOS transistor PFET2 is brought into the ON state, the plurality of N-channel type MOS transistors MN1 are brought into the ON state, so that the voltage of the ground node ND2 of the logic circuit block 113 becomes the ground potential Vss.

According to the modification, the following effects can be obtained.

1) In the modification, the same effects as those of the first embodiment can be obtained.

2) Since the plurality of P-channel type MOS transistors MP1 are brought into the OFF state in the shutdown state, the logic circuit block 113 is shut down from the power supply wiring L1. Therefore, even when the semiconductor device 1 is in a high temperature state, the current consumption of the semiconductor device 1 can be reduced.

3) Since the potential difference between the first potential LGVdd and the second potential LGVss is supplied to the logic circuit block 113 in the standby state, the internal logic circuit constituting the logic circuit block 113 can hold the signal state in the normal operation state. Namely, the potential difference between the first potential LGVdd and the second potential LGVss is set to such a potential difference that the internal logic circuit constituting the logic circuit block 113 can hold the signal state in the normal operation state.

### Second Embodiment

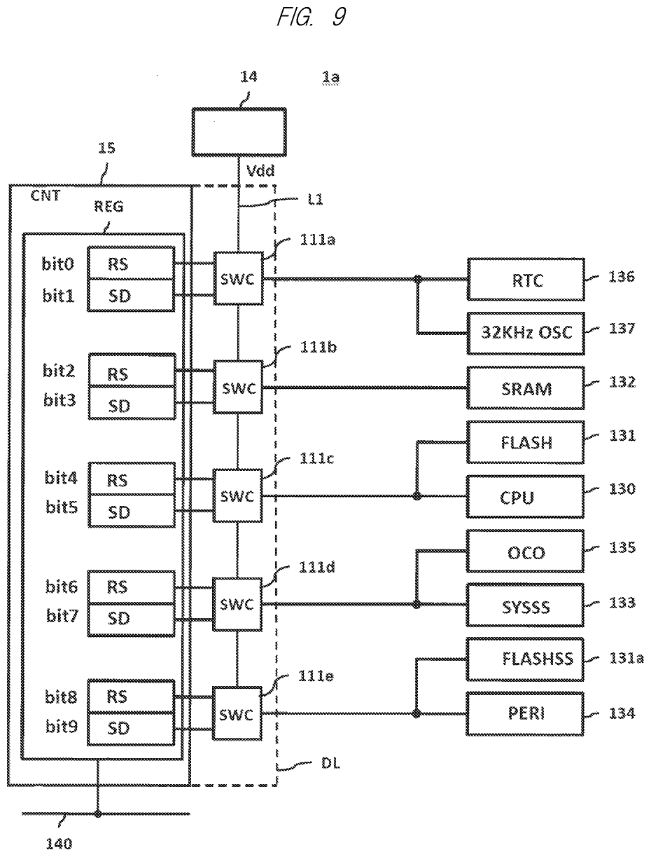

In the second embodiment, a configuration in which the switch circuit 111 is provided for each of a plurality of functional blocks included in a microcontroller (MCU) which is a semiconductor device will be described. FIG. 8 is a diagram illustrating a configuration example of the semiconductor device according to the second embodiment. FIG. 9 is a diagram illustrating a supply path of the power supply potential of the semiconductor device of FIG. 8. Note that the illustration of the ground wiring L2 described with reference to FIG. 1 and FIG. 2 is omitted in FIG. 9 for the sake of simplification of the drawing.

A semiconductor device 1a is formed on one semiconductor chip such as single crystal silicon by using a known manufacturing method of a CMOS transistor. As shown in FIG. 8, the microcontroller (MCU) which is the semiconductor device 1a includes a plurality of functional blocks 130 to 137, the analog-to-digital conversion circuit (ADC) 13, the power supply circuit (PSC) 14, the control circuit 15, a bus 140, etc. The bus 140 is configured to mutually connect the circuits (13, 14, 15, 130-136) in the microcontroller (MCU).

In this example, the plurality of functional blocks 130 to 137 include a central processing unit (CPU) 130, a flash memory (FLASH (registered trademark)) 131 as a non-volatile memory, a static random access memory (SRAM) 132 as a volatile memory, a system control device (SYSSS) 133, a peripheral circuit (PERI) 134 including a timer circuit (TM) 134a and a serial communication circuit (SCI) 134b, an on-chip clock generation circuit (OCO) 135 that generates an operation clock CLK of the semiconductor device la, a real-time clock generation circuit (RTC) 136 that counts the current time, an oscillation circuit (OSC) 137 that generates a 32 KHz reference clock signal supplied to the RTC 136, and the like. The FLASH 131 includes a flash sub-control circuit (FLASHSS) 131a that controls the operation of the FLASH 131.

The clock function, which is a real-time clock operation (RTC operation), is realized by the real-time clock generation circuit (RTC) 136 and the oscillation circuit (OSC) 137. Namely, the real-time clock operation (RTC operation) can also be defined as an operation of counting the current time.

As shown in FIG. 9, the control circuit CNT includes a control register REG connected to the bus 140. The control register REG includes a plurality of control bits bit0to bit9. The state of each of the plurality of control bits bit0to bit9 can be set by, for example, the CPU 130 or the like via the bus 140. The control bits bit0, bit2, bit4, bit6, and bit8 are provided to set the state of the standby signal RS. The control bits bit1, bit3, bit5, bit7, and bit9 are provided to set the state of the shutdown signal SD.

Each of the switch circuits (SWC) 111a to 111e has the same configuration as the switch circuit 111 described with reference to FIG. 2, and can take the three states (ST1 to ST3) described with reference to FIG. 4. Note that the switch circuits (SWC) 111a to 111e may be configured to be included in the control circuit CNT as shown by the dotted line DL in FIG. 9.

The switch circuit 111a is controlled by the control bits bit0 and bit1, and controls the supply of the power supply potential Vdd, the supply of the first potential LGVdd, and the shutdown of the supply of the power supply potential Vdd to the power supply node ND1 of each of the RTC 136 and the OSC 137. The switch circuit 111b is controlled by the control bits bit2 and bit3, and controls the supply of the power supply potential Vdd, the supply of the first potential LGVdd, and the shutdown of the supply of the power supply potential Vdd to the power supply node ND1 of the SRAM 132. The switch circuit 111c is controlled by the control bits bit4 and bit5, and controls the supply of the power supply potential Vdd, the supply of the first potential LGVdd, and the shutdown of the supply of the power supply potential Vdd to the power supply node ND1 of each of the FLASH 131 and the CPU 130. The switch circuit 111d is controlled by the control bits bit6 and bit7, and controls the supply of the power supply potential Vdd, the supply of the first potential LGVdd, and the shutdown of the supply of the power supply potential Vdd to the power supply node ND1 of each of the OCO 135 and the SYSSS 133. The switch circuit 111e is controlled by the control bits bit8 and bit9, and controls the supply of the power supply potential Vdd, the supply of the first potential LGVdd, and the shutdown of the supply of the power supply potential Vdd to the power supply node ND1 of each of the FLASHSS 131a and the PERI 134.

In FIG. 9, the switch circuits 111a to 111e are provided for each functional block, and the three states (ST1, ST2, ST3) of FIG. 4 can be individually controlled for each functional block by the control of the register REG. The functional blocks are divided for the circuits required for the RTC operation (RTC 136, OSC 137), the system control circuits for controlling the operation mode of the semiconductor device 1a (SYSSS 133, OCO 135), and the circuits not required for the standby state and the RTC operation (hereinafter referred to as (Standby state and RTC operation)) (SRAM 132, FLASH 131, CPU 130, FLASHSS 131a, PERI 134).

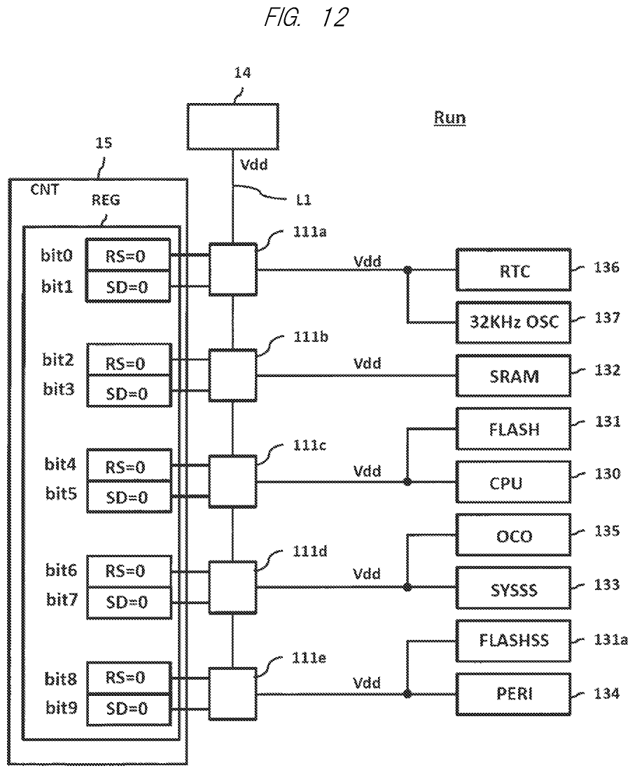

Here, (Standby state and RTC operation) is the state in which the RTC operation is being executed (state in which the power supply potential Vdd is supplied to the RTC 136 and the OSC 137), and can be defined as the state in which the first potential LGVdd is supplied to the system control circuit (SYSSS 133, 000135) and the first potential LGVdd is supplied to logic circuits (FLASH 131, CPU 130, FLASHSS 131a, PERI 134) other than the RTC 136, the OSC 137, the SYSSS 133, and the OCO 135 or the supply of the power supply potential Vdd to the logic circuits (FLASH 131, CPU 130, FLASHSS 131a, PERI 134) is shut down. Namely, the first standby mode (Standby1) and the second standby mode (Standby2) of FIG. 11 described later correspond to (Standby state and RTC operation).

Further, (Shutdown state and RTC operation) is the state in which the RTC operation is being executed (state in which the power supply potential Vdd is supplied to the RTC 136 and the OSC 137), and is the state in which the supply of the power supply potential Vdd to the system control circuit (SYSSS 133, OCO 135) and the logic circuit (FLASH 131, CPU 130, FLASHSS 131a, PERI 134) is shut down. Namely, the shutdown mode (Shutdown) of FIG. 11 described later corresponds to (Shutdown state and RTC operation).

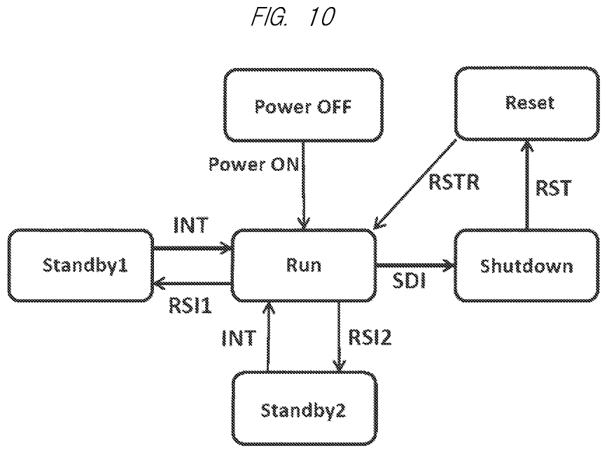

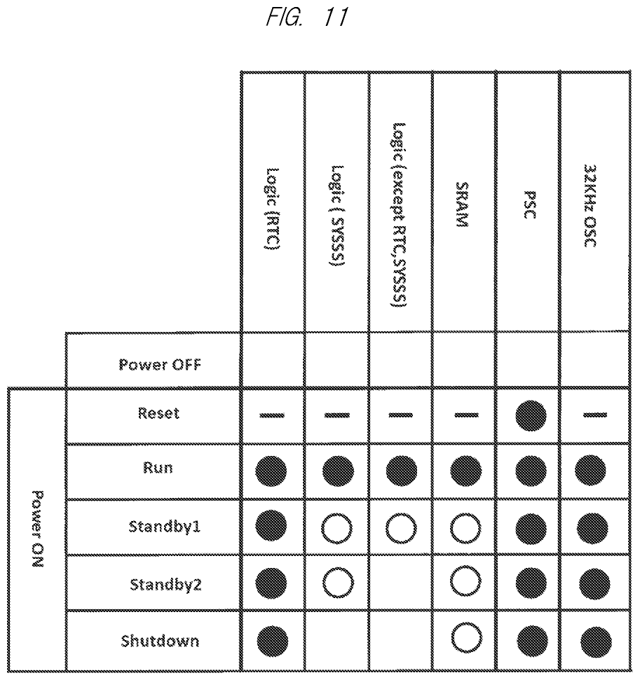

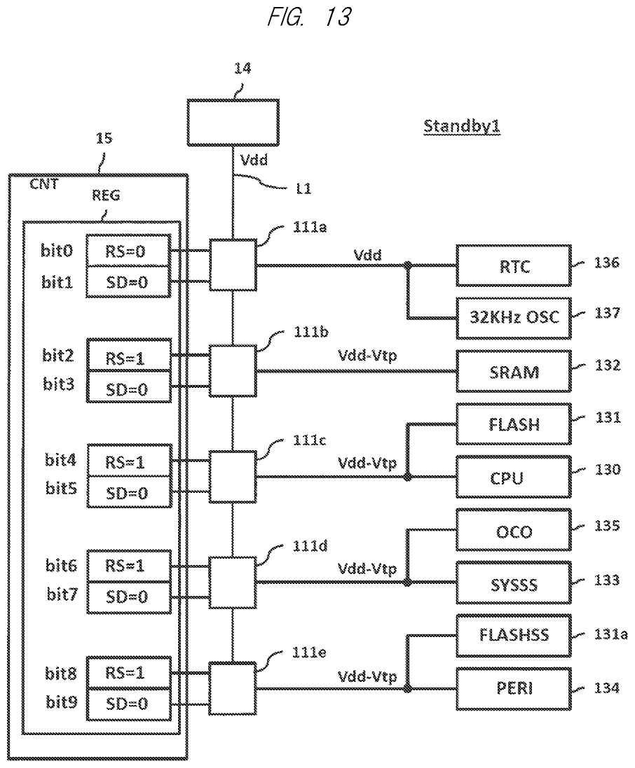

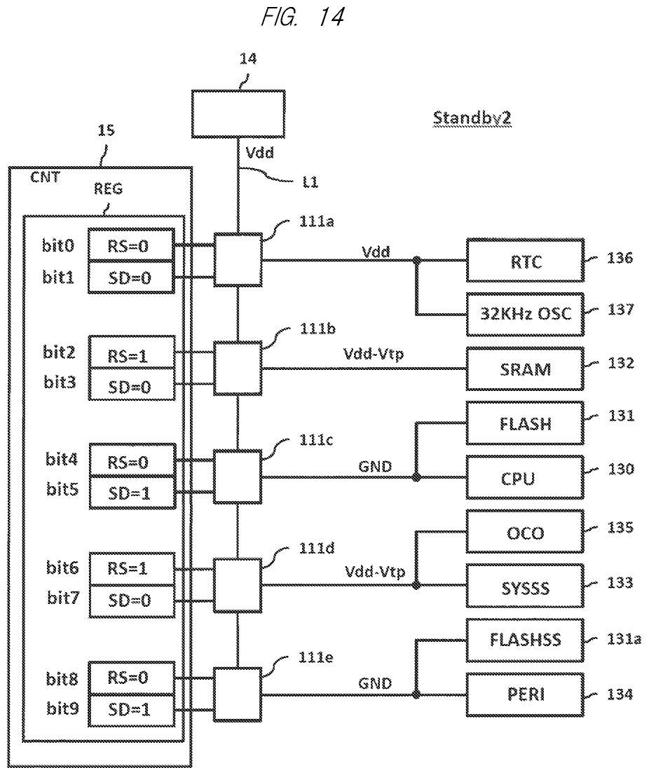

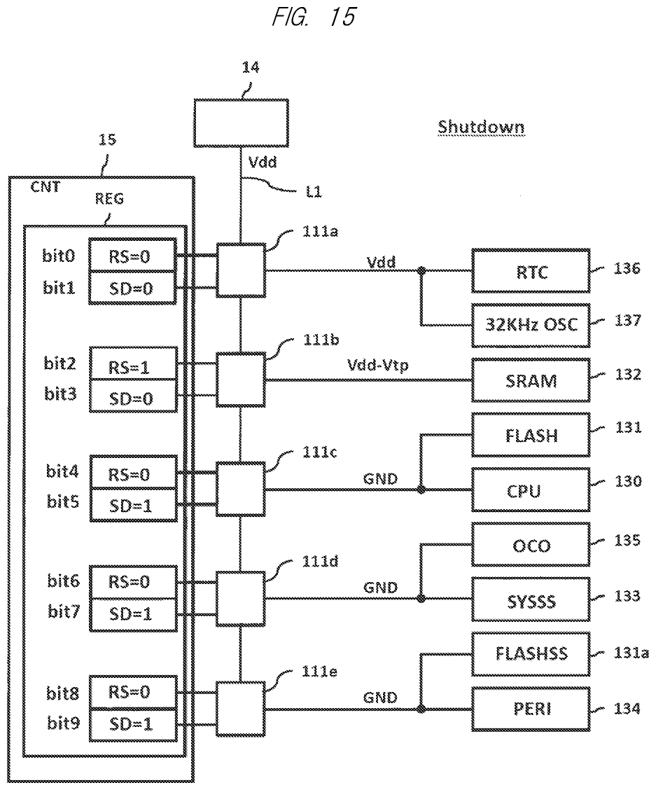

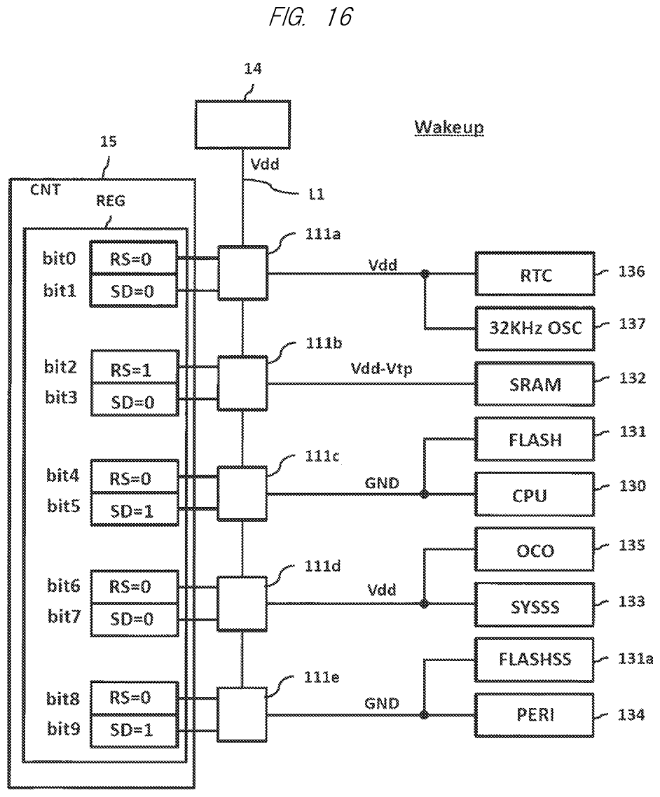

FIG. 10 is a diagram showing the operation modes of the semiconductor device and the state transition thereof. FIG. 11 is a diagram illustrating the operation modes of FIG. 10 and the state of each functional block of FIG. 9. FIG. 12 is a diagram showing an example of a setting state of a control register in a normal operation mode. FIG. 13 is a diagram showing an example of the setting state of the control register in a first standby mode. FIG. 14 is a diagram showing an example of the setting state of the control register in a second standby mode. FIG. 15 is a diagram showing an example of the setting state of the control register in a shutdown mode. FIG. 16 is a diagram showing an example of the setting state of the control register during the transition from the second standby mode to the normal operation state. In FIG. 14 to FIG. 16, the ground potential GND shows the state in which the power supply node ND1 of the corresponding functional block is set to the ground potential GND based on the OFF state of the plurality of P-channel type MOS transistors MP1 of the corresponding switch circuit.

As shown in FIG. 10, the operation modes of the semiconductor device 1a include a power-off state (Power OFF) in which the power supply potential VCC is not supplied and a power-on state (Power ON) in which the power supply potential VCC is supplied. The power-on state (Power ON) has the reset mode (Reset), the normal operation state (Run) (also referred to as the normal operation mode), the first standby mode (Standby1), the second standby mode (Standby2), and the shutdown mode (Shutdown).

FIG. 11 shows the states of the following circuits 1) to 6) in each operation mode. Each of the circuits 1) to 6) is as follows.

Circuit 1) Logic circuit (Logic (RTC)): RTC 136

Circuit 2) Logic circuit (Logic (SYSSS)): SYSSS 133, OCO 135

Circuit 3) Logic circuits other than RTC 136 and SYSSS 133 (Logic (except RTC, SYSSS)): CPU 130, FLASH 131, FLASHSS 131a, PERI 134

Circuit 4) SRAM: SRAM 132

Circuit 5) PSC: PSC 14

Circuit 6) OSC: OSC 137

The symbols shown in FIG. 11 are as follows.

Black circle ●: It indicates the state in which the power supply potential VCC or the power supply potential Vdd from the switch circuit is supplied to the corresponding circuit, and the corresponding circuit can select an operation state or a stopped state.

White circle ○: It indicates the state in which the first potential LGVdd is supplied to the corresponding circuit from the switch circuit, and the corresponding circuit maintains the logical state before the transition. Namely, the corresponding circuit is in the resume standby state.

Horizontal bar (-): It indicates that the corresponding circuit is in the stopped state. However, the power supply potential Vdd is supplied to the corresponding circuit from the switch circuit.

Blank (no symbol): It indicates that the power supply potential VCC or the power supply potential Vdd from the switch circuit is not supplied to the corresponding circuit in the power-off state, and the supply of the power supply potential Vdd is shutdown by the switch circuit in the power-on state.

Next, each operation mode shown in FIG. 11 will be described.

Reset mode (Reset):

The power supply potential VCC is supplied to the power supply circuit (PSC) 14 which is the circuit 5), and the power supply circuit (PSC) 14 generates the power supply potential Vdd which is the internal power supply potential.

Normal operation mode (Run):

The power supply potential Vdd generated from the power supply circuit (PSC) 14 is supplied to each of the power supply nodes ND1 of the circuits 1) to 4) and 6) via the switch circuits 111a to 111e.

Namely, in the normal operation mode (Run), as shown in FIG. 12, the control bits bit0, bit2, bit4, bit6, and bit8 are set to the low level (0) state (RS=0), and the control bits bit1, bit3, bit5, bit7, and bit9 are set to the low level (0) state (SD=0).

First Standby Mode (Standby1):

The power supply potential Vdd generated from the power supply circuit (PSC) 14 is supplied to each of the power supply nodes ND1 of the circuits 1) and 6) via the switch circuit 111a. As a result, the RTC operation can be performed.

The first potential LGVdd is supplied from the switch circuits 111d, 111c, 111e, and 111b to each of the power supply nodes ND1 of the circuits 2), 3), and 4). The circuits 2), 3) and 4) are in the standby state.

Namely, in the first standby mode, as shown in FIG. 13, the control bit bit0is set to the low level (0) state (RS=0), and the control bits bit2, bit4, bit6, and bit8 are set to the high level (1) state (RS=1). The control bits bit1, bit3, bit5, bit7, and bit9 are set to the low level (0) state (SD=0).

Second Standby Mode (Standby2):

The power supply potential Vdd generated from the power supply circuit (PSC) 14 is supplied to each of the power supply nodes ND1 of the circuits 1) and 6) via the switch circuit 111a. As a result, the RTC operation can be performed.

The first potential LGVdd is supplied from the switch circuits 111d and 111b to each of the power supply nodes ND1 of the circuits 2) and 4). The circuits 2) and 4) are in the standby state.

The supply of the power supply potential Vdd to the power supply node ND1 of the circuit 3) is shut down by the switch circuits 111c and 111e. As a result, the circuit 3) is in the shutdown state.

Namely, in the second standby mode, as shown in FIG. 14, the control bits bit0, bit4, and bit8 are set to the low level (0) state (RS=0), and the control bits bit2 and bit6 are set to the high level (1) state (RS=1). The control bits bit1, bit3, and bit7 are set to the low level (0) state (SD=0), and the control bits bit5 and bit9 are set to the high level (1) state (SD=1).

Shutdown Mode (Shutdown):

The power supply potential Vdd generated from the power supply circuit (PSC) 14 is supplied to each of the power supply nodes ND1 of the circuits 1) and 6) via the switch circuit 111a. As a result, the RTC operation can be performed.

The first potential LGVdd is supplied from the switch circuit 111b to the power supply node ND1 of the circuit 4). The circuit 4) is in the standby state.

The supply of the power supply potential Vdd to each of the power supply nodes ND1 of the circuits 2) and 3) is shut down by the switch circuits 111d, 111c, and 111e. As a result, the circuits 2) and 3) are in the shutdown state.

Namely, in the shutdown mode, as shown in FIG. 15, the control bits bit0, bit2, bit4, bit6, and bit8 are set to the low level (0) state (RS=0), and the control bit bit2 is set to the high level (1) state (RS=1). The control bits bit1 and bit3 are set to the low level (0) state (SD=0), and the control bits bit5, bit7 and bit9 are set to the high level (1) state (SD=1).

(Description of State Transition)

Returning to FIG. 10, the state transition will be described. In the following description, the state transition will be described by using a shutdown instruction (SDI), a first standby instruction (RSI1), and a second standby instruction (RSI2). Note that the shutdown instruction (SDI), the first standby instruction (RSI1), and the second standby instruction (RSI2) can be changed to a register setting instruction (or bit operation instruction) for setting the control bit of the control register REG and a stop instruction (STOP) that is executed after executing the register setting instruction. When the CPU 130 executes the register setting instruction and then executes the stop instruction, the CPU 130 is in the stopped state and is then in the state of waiting for a process or instruction to be executed next.

When the power supply potential VCC is applied to the semiconductor device 1a (Power ON), the semiconductor device 1a makes a transition from the power-off state to the normal operation state (Run).

When the CPU 130 executes the shutdown instruction (SDI) in the normal operation mode, the semiconductor device 1a makes a transition to the shutdown mode. By executing the shutdown instruction, each control bit of the control register REG is set as shown in FIG. 15.

In the shutdown mode, the semiconductor device 1a makes a transition from the shutdown mode to the reset mode based on the occurrence of the reset factor (RST) of the semiconductor device 1a. At this time, the reset process is executed, the control bit bit2 is changed from the high level (1) state (RS=1) to the low level (0) state (SD=0), and the control bits bit5, bit7, and bit9 are changed from the high level (1) state (SD=1) to the low level (0) state (SD=0). Thereafter, the reset mode is released (reset release RSTR), and the semiconductor device 1a makes a transition to the normal operation mode.

When the CPU 130 executes the first standby instruction (RSI1) in the normal operation mode, the semiconductor device 1a makes a transition to the first standbymode. By executing the first standby instruction, each control bit of the control register REG is set as shown in FIG. 13. In the first standby mode, the semiconductor device 1a makes a transition from the first standby mode to the normal operation mode based on the occurrence of the interrupt request signal (INT) which is the recovery factor trigger of the CPU 130. At this time, as shown in FIG. 12, each control bit of the control register REG is set.

When the CPU 130 executes the second standby instruction (RSI2) in the normal operation mode, the semiconductor device 1a makes a transition to the second standby mode. By executing the second standby instruction, each control bit of the control register REG is set as shown in FIG. 14. In the second standby mode, the semiconductor device 1a makes a transition from the second standby mode to the normal operation mode based on the occurrence of the interrupt request signal (INT) which is the recovery factor trigger of the CPU 130. When making the transition from the second standby mode to the normal operation mode, it is possible to interpose the wakeup (Wakeup) state shown in FIG. 16 (FIG. 14→FIG. 16→FIG. 12). In FIG. 16, the control bit bit6 is changed from the high level (1) state (RS=1) shown in FIG. 14 to the low level (0) state (RS=0).

According to the second embodiment, the following effects can be obtained.

1) In the second embodiment, the same effects as those of the first embodiment can be obtained.

2) Since the second standby mode (Standby2) shown in FIG. 11 is provided, the current consumption of the logic circuits other than the RTC 136, the SYSSS 133, and the OCO 135 (Logic (except RTC, SYSSS): CPU 130, FLASH 131, FLASHSS 131a, PERI 134) can be reduced while performing the RTC operation.

3) Since the shutdown mode (Shutdown) shown in FIG. 11 is provided, the current consumption of the logic circuits (Logic (SYSSS): SYSSS 133, OCO 135) and the logic circuits other than the RTC 136, the SYSSS 133, and the OCO 135 (Logic (except RTC, SYSSS): CPU 130, FLASH 131, FLASHSS 131a, PERI 134) can be reduced while performing the RTC operation. In the shutdown mode, in the high temperature state of the semiconductor device such as 85° C., the leakage current of the semiconductor device 1a can be reduced by about 75% as compared with the normal operation mode, and can be reduced by about 30% as compared with the first standby mode (Standby1).

4) By providing the control register REG including a plurality of control bits and setting the plurality of control bits without changing the output voltage of the power supply circuit 14, the transition from the shutdown mode to the normal operation mode can be made in a short time. Namely, it is possible to activate the normal operation mode from the shutdown mode at high speed.

5) Since the second standby mode and the shutdown mode are provided in 4) above, the current consumption of the semiconductor device can be reduced.

Although the invention made by the inventor has been specifically described above based on embodiments, it goes without saying that the present invention is not limited to the above-described embodiments and examples and can be variously modified.

What is claimed is:

1. A semiconductor device comprising:
a first wiring to which a power supply potential is supplied;
a second wiring to which a ground potential is supplied;
a logical circuit block including a power supply node, aground node connected to the second wiring, and a plurality of logical circuits; and
a switch circuit provided between the first wiring and the power supply node,
wherein the switch circuit includes a plurality of first P-channel type MOS transistors whose source-drain paths are connected between the first wiring and the power supply node, and
wherein the plurality of first P-channel type MOS transistors are brought into an OFF state, a diode-connected state, or an ON state.

2. The semiconductor device according to claim 1,
wherein the switch circuit further includes:
a second P-channel type MOS transistor;
a third P-channel type MOS transistor;
a buffer circuit having a fourth P-channel type MOS transistor and a first N-channel type MOS transistor;
an inverter; and
an AND circuit,
wherein a drain of the fourth P-channel type MOS transistor and a drain of the first N-channel type MOS transistor are connected to each gate electrode of the plurality of first P-channel type MOS transistors,
wherein a source of the fourth P-channel type MOS transistor is connected to drain electrodes of the plurality of first P-channel type MOS transistors via a source-drain path of the third P-channel type MOS transistor,
wherein a source of the first N-channel type MOS transistor is connected to the second wiring,
wherein a gate of the fourth P-channel type MOS transistor and a gate of the first N-channel type MOS transistor are connected to an output of the AND circuit,
wherein the second P-channel type MOS transistor has a gate connected so as to receive a shutdown signal, a source connected to the first wiring, and a drain connected to a drain of the third P-channel type MOS transistor,
wherein the inverter has an input that receives the shutdown signal and an output that is connected to a gate of the third P-channel type MOS transistor, and
wherein the AND circuit has a first input that receives the shutdown signal, a second input that receives a standby signal, and the output.

3. The semiconductor device according to claim 2,
wherein, when the shutdown signal is set to a low level, the plurality of first P-channel type MOS transistors are brought into the OFF state,
wherein, when the shutdown signal is set to a high level and the standby signal is set to a low level, the plurality of first P-channel type MOS transistors are brought into the diode-connected state, and
wherein, when the shutdown signal is set to the high level and the standby signal is set to a high level, the plurality of first P-channel type MOS transistors are brought into the ON state.

4. The semiconductor device according to claim 3,
wherein each of the plurality of logic circuits includes:
a P-channel type MOS transistor formed in an N-type well; and
an N-channel type MOS transistor formed in a P-type well,
wherein the power supply potential is supplied to the N-type well, and
wherein the ground potential is supplied to the P-type well.

5. A semiconductor device comprising:
a first wiring to which a power supply potential is supplied;
a second wiring to which a ground potential is supplied;
a first functional block, a second functional block, and a third functional block;
a first switch circuit, a second switch circuit, and a third switch circuit; and
a control circuit configured to control the first switch circuit, the second switch circuit, and the third switch circuit,
wherein each of the first functional block, the second functional block, and the third functional block includes:
a power supply node;
a ground node connected to the second wiring; and
a plurality of logic circuits,
wherein the first switch circuit includes a plurality of first P-channel type MOS transistors whose source-drain paths are connected between the first wiring and the power supply node of the first functional block,
wherein the second switch circuit includes a plurality of first P-channel type MOS transistors whose source-drain paths are connected between the first wiring and the power supply node of the second functional block,
wherein the third switch circuit includes a plurality of first P-channel type MOS transistors whose source-drain paths are connected between the first wiring and the power supply node of the third functional block, and
wherein the plurality of first P-channel type MOS transistors of each of the first switch circuit, the second switch circuit, and the third switch circuit are brought into an OFF state, a diode-connected state, or an ON state based on the control of the control circuit.

6. The semiconductor device according to claim 5,
wherein the first functional block includes a circuit configured to perform a real-time clock operation,
wherein the second functional block includes a system control circuit,
wherein the third functional block includes a central processing unit,
wherein the plurality of first P-channel type MOS transistors of the first switch circuit are brought into the ON state,
wherein the plurality of first P-channel type MOS transistors of the second switch circuit are brought into the diode-connected state, and
wherein the plurality of first P-channel type MOS transistors of the third switch circuit are brought into the OFF state.

7. The semiconductor device according to claim 5,
wherein the first functional block includes a circuit configured to perform a real-time clock operation,
wherein the second functional block includes a system control circuit,
wherein the third functional block includes a central processing unit,
wherein the plurality of first P-channel type MOS transistors of the first switch circuit are brought into the ON state,
wherein the plurality of first P-channel type MOS transistors of the second switch circuit are brought into the OFF state, and
wherein the plurality of first P-channel type MOS transistors of the third switch circuit are brought into the OFF state.

8. The semiconductor device according to claim 5,
wherein each of the first switch circuit, the second switch circuit, and the third switch circuit further includes:
a second P-channel type MOS transistor;
a third P-channel type MOS transistor;
a buffer circuit having a fourth P-channel type MOS transistor and a first N-channel type MOS transistor;
an inverter; and
an AND circuit,
wherein a drain of the fourth P-channel type MOS transistor and a drain of the first N-channel type MOS transistor are connected to each gate electrode of the plurality of first P-channel type MOS transistors,
wherein a source of the fourth P-channel type MOS transistor is connected to drain electrodes of the plurality of first P-channel type MOS transistors via a source-drain path of the third P-channel type MOS transistor,
wherein a source of the first N-channel type MOS transistor is connected to the second wiring,
wherein a gate of the fourth P-channel type MOS transistor and a gate of the first N-channel type MOS transistor are connected to an output of the AND circuit,
wherein the second P-channel type MOS transistor has a gate connected so as to receive a shutdown signal, a source connected to the first wiring, and a drain connected to a drain of the third P-channel type MOS transistor,
wherein the inverter has an input that receives the shutdown signal and an output that is connected to a gate of the third P-channel type MOS transistor, and
wherein the AND circuit has a first input that receives the shutdown signal, a second input that receives a standby signal, and the output.

9. The semiconductor device according to claim 8,
wherein the first functional block includes a circuit configured to perform a real-time clock operation,
wherein the second functional block includes a system control circuit,
wherein the third functional block includes a central processing unit, and
wherein the control circuit includes:
a first control bit configured to set a state of the shutdown signal of the first switch circuit;
a second control bit configured to set a state of the standby signal of the first switch circuit;
a third control bit configured to set a state of the shutdown signal of the second switch circuit;
a fourth control bit configured to set a state of the standby signal of the second switch circuit;
a fifth control bit configured to set a state of the shutdown signal of the third switch circuit; and
a sixth control bit configured to set a state of the standby signal of the third switch circuit.

10. The semiconductor device according to claim 9,
wherein each of the first control bit and the second control bit is set to a high level, and the plurality of first P-channel type MOS transistors of the first switch circuit are brought into the ON state,
wherein the third control bit is set to a high level and the fourth control bit is set to a low level, and the plurality of first P-channel type MOS transistors of the second switch circuit are brought into the diode-connected state, and
wherein the fifth control bit is set to a low level, and the plurality of first P-channel type MOS transistors of the third switch circuit are brought into the OFF state.

11. The semiconductor device according to claim 9,
wherein each of the first control bit and the second control bit is set to a high level, and the plurality of first P-channel type MOS transistors of the first switch circuit are brought into the ON state,
wherein the third control bit is set to a low level, and the plurality of first P-channel type MOS transistors of the second switch circuit are brought into the OFF state, and
wherein the fifth control bit is set to a low level, and the plurality of first P-channel type MOS transistors of the third switch circuit are brought into the OFF state.

12. A semiconductor device comprising:
a first wiring to which a power supply potential is supplied;
a second wiring to which a ground potential is supplied;
a first functional block, a second functional block, and a third functional block;
a first switch circuit, a second switch circuit, and a third switch circuit; and
a control circuit configured to control the first switch circuit, the second switch circuit, and the third switch circuit,
wherein each of the first functional block, the second functional block, and the third functional block includes:
a power supply node;
a ground node connected to the second wiring; and
a plurality of logic circuits,
wherein the first functional block includes a circuit configured to perform a real-time clock operation,
wherein the second functional block includes a system control circuit,
wherein the third functional block includes a central processing unit,
wherein the first switch circuit includes a plurality of first P-channel type MOS transistors whose source-drain paths are connected between the first wiring and the power supply node of the first functional block,
wherein the second switch circuit includes a plurality of first P-channel type MOS transistors whose source-drain paths are connected between the first wiring and the power supply node of the second functional block,
wherein the third switch circuit includes a plurality of first P-channel type MOS transistors whose source-drain paths are connected between the first wiring and the power supply node of the third functional block, and
wherein the plurality of first P-channel type MOS transistors of each of the first switch circuit, the second switch circuit, and the third switch circuit are brought into an OFF state, a diode-connected state, or an ON state based on the control of the control circuit.

13. The semiconductor device according to claim 12,
wherein the plurality of first P-channel type MOS transistors of the first switch circuit are brought into the ON state,
wherein the plurality of first P-channel type MOS transistors of the second switch circuit are brought into the diode-connected state, and
wherein the plurality of first P-channel type MOS transistors of the third switch circuit are brought into the OFF state.

14. The semiconductor device according to claim 12,
wherein the plurality of first P-channel type MOS transistors of the first switch circuit are brought into the ON state,
wherein the plurality of first P-channel type MOS transistors of the second switch circuit are brought into the OFF state, and
wherein the plurality of first P-channel type MOS transistors of the third switch circuit are brought into the OFF state.
